(19) United States
(12) Patent Application Publication
(10) Pub. No.: US 2025/0218810 A1
(43) Pub. Date: Jul. 3, 2025

(54) SUBSTRATE DRYING APPARATUS AND SUBSTRATE DRYING METHOD

(71) Applicant: SAMSUNG ELECTRONICS CO., LTD., Suwon-si (KR)

(72) Inventors: Junho YOON, Suwon-si (KR); Jihoon JEONG, Suwon-si (KR); Taeheon KIM, Suwon-si (KR); Junho LEE, Suwon-si (KR); Younghoo KIM, Suwon-si (KR); Jongwon LEE, Suwon-si (KR); Jiwoong JUNG, Suwon-si (KR)

(73) Assignee: SAMSUNG ELECTRONICS CO., LTD., Suwon-si (KR)

(21) Appl. No.: 19/008,381

(22) Filed: Jan. 2, 2025

(30) Foreign Application Priority Data
Jan. 3, 2024 (KR) 10-2024-0001063

(51) Int. Cl. H01L 21/67

(52) U.S. Cl. CPC H01L 21/67034

(57) ABSTRACT

A substrate drying apparatus includes a process chamber including a processing space for drying a residual liquid remaining on a surface of a substrate, a first fluid supply device configured to supply a first fluid to the processing space, wherein the solubility of the residual liquid in the first fluid is a first solubility, a second fluid supply device configured to supply a second fluid in a supercritical state to the processing space, wherein the solubility of the residual liquid in the second fluid is a second solubility that is greater than the first solubility, and an exhaust device configured to discharge a waste fluid within the processing space of the process chamber to the outside of the process chamber.

### CROSS-REFERENCE TO RELATED APPLICATION

This application is based on and claims priority to Korean Patent Application No. 10-2024-0001063, filed on Jan. 3, 2024, in the Korean Intellectual Property Office, the disclosure of which is incorporated by reference herein in its entirety.

### BACKGROUND

The technical idea of the present disclosure relates to a substrate drying apparatus and a substrate drying method, and more specifically, to a substrate drying apparatus and a substrate drying method for drying a substrate through the use of a supercritical fluid.

As the miniaturization of semiconductor devices is required, an extreme ultra-violet (EUV) lithography method with a very short wavelength has been proposed. Using this EUV lithography, fine patterns maybe formed by using photoresist patterns with small critical dimensions and high aspect ratios. To minimize the falling or collapsing of the fine patterns in the process of forming the fine patterns, a drying process using a supercritical fluid is used, but improvements are still needed.

### SUMMARY

A task to be solved by the technical idea of the present disclosure is to provide a substrate drying apparatus and a substrate drying method for suppressing a phenomenon of fine patterns collapsing when drying a substrate.

Also, a task to be solved by the technical idea of the present disclosure is not limited to the task mentioned above, and other tasks may be clearly understood by those skilled in the art from the description below.

In order to solve the above task, the technical idea of the present disclosure provides a substrate drying apparatus including a process chamber including a processing space for drying a residual liquid remaining on a surface of a substrate, a substrate support configured to support the substrate within the process chamber, a first fluid supply device configured to supply a first fluid to the processing space through a first supply pipe penetrating the process chamber, wherein the solubility of the residual liquid in the first fluid is a first solubility, a second fluid supply device configured to supply a second fluid in a supercritical state to the processing space through a second supply pipe penetrating the process chamber, wherein the solubility of the residual liquid in the second fluid is a second solubility that is greater than the first solubility, and an exhaust device configured to discharge a waste fluid within the processing space of the process chamber to the outside of the process chamber through an exhaust pipe penetrating the process chamber.

In order to solve the above task, the technical idea of the present disclosure provides a substrate drying method including loading a substrate with a residual liquid located on its surface onto a substrate support within a process chamber, supplying a first fluid to a processing space within the process chamber and increasing the pressure of the processing space, supplying a second fluid in a supercritical state to the processing space within the process chamber and dissolving the residual liquid located on the surface of the substrate, and discharging a waste fluid within the processing space to the outside of the process chamber. The solubility of the residual liquid in the first fluid is less than the solubility of the residual liquid in the second fluid.

In order to solve the above task, the technical idea of the present disclosure provides a substrate drying method including loading a substrate with a residual liquid located on its surface onto a substrate support within a process chamber, supplying, by a first fluid supply device, a first fluid in a supercritical state to a processing space within the process chamber and increasing the pressure of the processing space, supplying, by a second fluid supply device, a second fluid in a supercritical state to the processing space within the process chamber and dissolving the residual liquid located on the surface of the substrate in the second fluid, and discharging a waste fluid within the processing space to the outside of the process chamber. The substrate includes a plurality of fine patterns protruding upward from an upper face of the substrate. In the operation of increasing the pressure of the processing space, the residual liquid covers the plurality of fine patterns of the substrate. The second fluid is supplied to the processing space when the pressure of the processing space reaches a process pressure. The first fluid and the second fluid have different constituent materials. The solubility of the residual liquid in the first fluid is less than the solubility of the residual liquid in the second fluid.

### BRIEF DESCRIPTION OF DRAWINGS

Embodiments will be more clearly understood from the following detailed description taken in conjunction with the accompanying drawings in which:

FIG. 1 is a diagram schematically illustrating a substrate treating apparatus according to an embodiment;

FIG. 2 is a cross-sectional view schematically illustrating a substrate drying apparatus according to an embodiment;

FIG. 3 is a diagram illustrating a construction of a first fluid supply device and second fluid supply device of the substrate drying apparatus of FIG. 2;

FIG. 4 is a cross-sectional view schematically illustrating a substrate drying apparatus according to an embodiment;

FIG. 5 is a flowchart illustrating a substrate drying method according to an embodiment;

FIG. 6 is a graph illustrating the change of pressure of a processing space while substrate drying is in progress; and

FIGS. 7 to 10 are cross-sectional views illustrating a substrate drying method in accordance with a process sequence according to an embodiment.

### DETAILED DESCRIPTION

Since the present embodiments may have various changes and have various forms, some embodiments will be illustrated in the drawings and described in detail. However, this is not intended to limit the present embodiments to a specifically disclosed form.

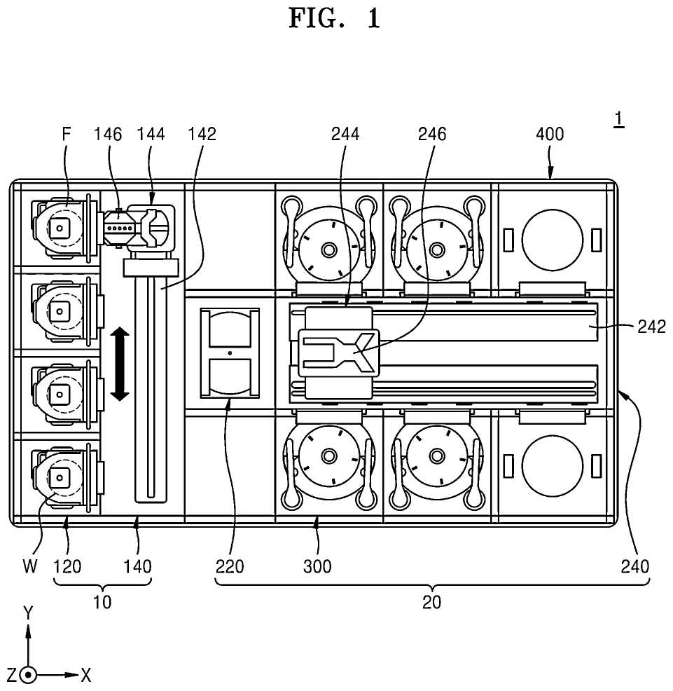

FIG. 1 is a diagram schematically illustrating a substrate treating apparatus 1 according to an embodiment.

Referring to FIG. 1, the substrate treating apparatus 1 may include an index module 10 and a treating module 20. According to an embodiment, the index module 10 and the treating module 20 may be arranged in one direction.

Hereinafter, the direction in which the index module 10 and the treating module 20 are arranged is defined as a first horizontal direction (X direction). When viewed from the top, a direction perpendicular to the first horizontal direction (X direction) is defined as a second horizontal direction (Y direction), and a direction perpendicular to a plane including all of the first horizontal direction (X direction) and the second horizontal direction (Y direction) is defined as a vertical direction (Z direction).

The index module 10 may include a load port 120 and an index frame 140. The index module 10 may transfer a substrate W from a container F where the substrate W is accommodated to the treating module 20 treating the substrate W. The index module 10 may accommodate the substrate W treated completely by the treating module 20 in the container F.

The container F where the substrate W is accommodated may be seated on the load port 120. The load port 120 may be located at an opposite side of the treating module 20, based on the index frame 140.

In some embodiments, a plurality of load ports 120 may be provided. The plurality of load ports 120 may be arranged in a row in the second horizontal direction (Y direction). The number of load ports 120 may vary depending on the process efficiency, footprint conditions, etc. of the treating module 20.

The container F may include a plurality of slots (not shown). The slots (not shown) may accommodate the substrates W arranged horizontally with respect to the ground. The container F may include an airtight container such as a front opening unified pod (FOUP). For example, the container F may be seated on the load port 120 by a transportation means (not shown) such as an overhead transfer, an overhead conveyor, or an automatic guided vehicle, or by an operator.

The index frame 140 may include an index rail 142 and an index robot 144. The index rail 142 may extend in the second horizontal direction (Y direction). The index robot 144 may move along the index rail 142 and transfer the substrate W to the treating module 20. The index robot 144 may transfer the substrate W between the index module 10 and a buffer unit 220.

The index robot 144 may include an index hand 146. The substrate W may be seated on the index hand 146. The index hand 146 may move in the second horizontal direction (Y direction) on the index rail 142. For example, the index hand 146 may move forward and backward along the index rail 142. Also, the index hand 146 may be provided to be rotatable about a vertical direction (Z direction). Also, the index hand 146 may be provided to be vertically movable in the vertical direction (Z direction).

In some embodiments, a plurality of index hands 146 may be provided. The plurality of index hands 146 may be provided to be spaced apart in up and down directions. The plurality of index hands 146 may move forward, backward, and rotationally independently of each other.

The treating module 20 may include the buffer unit 220, a transfer frame 240, a substrate liquid treating apparatus 300, and a substrate drying apparatus 400.

The buffer unit 220 may provide a space for temporarily seating the substrate W brought into the treating module 20 and the substrate W taken out of the treating module 20. The transfer frame 240 may provide a transfer space for transferring the substrate W between the buffer unit 220, the substrate liquid treating apparatus 300, and the substrate drying apparatus 400.

The buffer unit 220 may be arranged between the index frame 140 and the transfer frame 240. The buffer unit 220 may be located at one end of the transfer frame 240. The buffer unit 220 may include a plurality of slots (not shown) in which substrates W are arranged. The plurality of slots may be arranged to be spaced apart from each other in the vertical direction (Z direction).

A front face and rear face of the buffer unit 220 may be open. The front face of the buffer unit 220 may include a face facing the index module 10, and the rear face of the buffer unit 220 may include a face facing the transfer frame 240. The index robot 144 may bring the substrate W into the buffer unit 220 through the front face of the buffer unit 220, and a transfer robot 244 may take the substrate W out from the buffer unit 220 through the rear face of the buffer unit 220.

The transfer frame 240 may extend in the first horizontal direction (X direction). The substrate liquid treating apparatus 300 and the substrate drying apparatus 400 may be spaced apart from each other in the second horizontal direction (Y direction) and be arranged at both sides of the transfer frame 240. For example, the transfer frame 240 and the substrate liquid treating apparatus 300 may be arranged in the second horizontal direction (Y direction). Also, the transfer frame 240 and the substrate drying apparatus 400 may be arranged in the second horizontal direction (Y direction). In some embodiments, substrate liquid treating apparatuses 300 may be arranged relatively closer to the buffer unit 220 than the substrate drying apparatuses 400.

The transfer frame 240 may include a guide rail 242 and the transfer robot 244. The guide rail 242 may extend in the first horizontal direction (X direction). The transfer robot 244 may move linearly in the first horizontal direction (X direction) on the guide rail 242.

The transfer robot 244 may transfer the substrate W between the buffer unit 220, the substrate liquid treating apparatus 300, and the substrate drying apparatus 400. The transfer robot 244 may include a transfer hand 246 configured to seat the substrate W. The transfer hand 246 may move in the first horizontal direction (X direction) on the guide rail 242. For example, the transfer hand 246 may move forward and backward along the guide rail 242. Also, the transfer hand 246 may rotate about the vertical direction (Z direction) that is a rotation axis and move in the vertical direction (Z direction).

In some embodiments, a plurality of transfer hands 246 may be provided. The plurality of transfer hands 246 may be provided to be spaced apart in up and down directions. The plurality of transfer hands 246 may move forward, backward, and rotationally independently of each other.

The substrate liquid treating apparatus 300 may perform a liquid treating process of supplying a liquid onto the substrate W and liquid treating the substrate W. The substrate drying apparatus 400 may perform a drying process of removing a liquid remaining on the substrate W.

The substrate liquid treating apparatus 300 and the substrate drying apparatus 400 may perform a substrate cleaning process. For example, the substrate cleaning process may be sequentially performed in the substrate liquid treating apparatus 300 and the substrate drying apparatus 400.

For example, the substrate liquid treating apparatus 300 may supply a chemical, a cleaning liquid, a rinsing liquid, and/or an organic solvent onto the substrate W and treat the substrate W. For example, the substrate drying apparatus 400 may perform a drying process of removing a residual liquid remaining on a surface of the substrate W by using a supercritical fluid. The substrate drying apparatus 400 is described below in more detail.

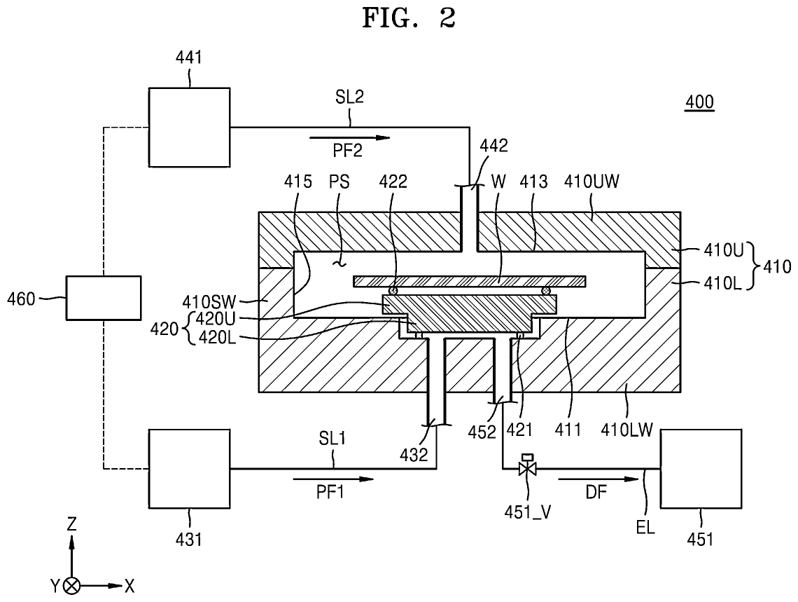

FIG. 2 is a cross-sectional view schematically illustrating a substrate drying apparatus 400 according to an embodiment.

The substrate drying apparatus 400 may include a process chamber 410, a substrate support 420, a first fluid supply device 431, a first supply pipe 432, a second fluid supply device 441, a second supply pipe 442, an exhaust device 451, and an exhaust pipe 452.

The process chamber 410 may provide a processing space PS for processing a substrate W. The process chamber 410 may seal the processing space PS from the outside while processing the substrate W. For example, a state in which the processing space PS is closed may be referred to as a closed state of the process chamber 410, and a state in which the processing space PS is open to the external atmosphere may be referred to as an open state of the process chamber 410.

The processing space PS may be defined by a lower face 411, an upper face 413, and a side face 415 of the process chamber 410. In other words, the processing space PS may be defined by a lower wall 410LW including the lower face 411 of the process chamber 410, an upper wall 410UW including the upper face 413 of the process chamber 410, and a side wall 410SW defining the side face 415 of the process chamber 410.

In some embodiments, the process chamber 410 may include a lower body 410L and an upper body 410U. The upper body 410U may be disposed to be spaced apart from the lower body 410L. The upper body 410U may be coupled onto the lower body 410L to cover the lower face 411 included in the lower body 410L. For example, each of the upper body 410U and the lower body 410L may include, for example, a metal material.

In some embodiments, when the upper body 410U is coupled with the lower body 410L, the process chamber 410 may be in a closed state. When the upper body 410U is separated from the lower body 410L, the process chamber 410 may be in an open state. For example, conversion between the closed state and open state of the process chamber 410 may be implemented by a lifting device (not shown) configured to move the upper body 410U in a vertical direction (Z direction) with respect to the lower body 410L.

The substrate support 420 may be provided in the processing space PS and support the substrate W. The substrate support 420 may support the substrate W so that an upper face of the substrate W faces the upper face 413 of the process chamber 410 and a lower face of the substrate W faces the lower face 411 of the process chamber 410.

In some embodiments, the substrate support 420 may have a shape corresponding to the substrate W, for example, a disk shape. The substrate support 420 may be made of, for example, a metal material or a ceramic material. In some embodiments, the substrate support 420 may include an electrostatic chuck supporting the substrate W by an electrostatic force or a vacuum chuck supporting the substrate W by negative pressure.

In some embodiments, the substrate support 420 may include a lower structure 420L having a first diameter and an upper structure 420U having a second diameter that is greater than the first diameter. However, this is a division for convenience of explanation, and the lower structure 420L and upper structure 420U may be a one-body structure and may form the substrate support 420.

The lower structure 420L of the substrate support 420 may be supported by a support pillar 421 located on the lower face 411 of the process chamber 410. The lower structure 420L of the substrate support 420 may be spaced apart from the lower face 411 of the process chamber 410 by the height of the support pillar 421.

A support pin 422 may be disposed on the upper structure 420U of the substrate support 420, and the substrate W may be supported by the support pin 422 that is in contact with the lower face of the substrate W. In some embodiments, the second diameter of the upper structure 420U of the substrate support 420 may be less than the diameter of the substrate W.

In some embodiments, the substrate support 420 may be disposed above the lower face 411 of the process chamber 410 to cover the first supply pipe 432. The substrate support 420 may be located between the first supply pipe 432 and the substrate W and may be configured to adjust a flow direction of a first fluid PF1 sprayed through the first supply pipe 432. The substrate support 420 may block the first fluid PF1 sprayed through the first supply pipe 432 from being sprayed directly onto the surface of the substrate W.

The first fluid supply device 431 may supply the first fluid PF1 to the processing space PS. The first fluid supply device 431 may supply the first fluid PF1 in a gaseous state or supercritical state to the process chamber 410. The first fluid PF1 may be supplied to the processing space PS, thereby increasing the pressure of the processing space PS.

For example, the first fluid supply device 431 may supply the first fluid PF1 to the processing space PS in the operation of increasing the pressure of the processing space PS during a substrate drying process. When the pressure of the processing space PS is increased using the first fluid PF1, the dissolution of an unnecessary residual liquid may be suppressed and thus a falling, collapsing, or leaning phenomenon (hereinafter, referred to as a leaning phenomenon) occurring in a fine pattern on the substrate W may be suppressed.

The first fluid supply device 431 may be connected to the first supply pipe 432 penetrating the process chamber 410 through a first supply line SL1. The first fluid supply device 431 may spray the first fluid PF1 into the processing space PS through the first supply pipe 432. The first supply pipe 432 may be located in the lower wall 410LW of the process chamber 410. For example, the first supply pipe 432 may penetrate the lower wall 410LW of the process chamber 410.

In some embodiments, the first supply pipe 432 may extend downward from the lower face 411 of the process chamber 410. For example, one end of the first supply pipe 432 may be located inside the process chamber 410, and the other end of the first supply pipe 432 may be located outside the process chamber 410. The first fluid supply device 431 may be connected to the other end of the first supply pipe 432.

In some embodiments, the one end of the first supply pipe 432 may overlap the lower structure 420L in a vertical direction (Z direction). Accordingly, the first fluid PF1 sprayed through the first supply pipe 432 is not directly sprayed to the substrate W and may reach the lower structure 420L before the substrate W.

In some embodiments, a cross-section of the first supply pipe 432 perpendicular to a direction of extension of the first supply pipe 432 may have a circular or oval shape. In some embodiments, the cross-section of the first supply pipe 432 perpendicular to the direction of extension of the first supply pipe 432 may also have a polygonal shape such as a square.

The second fluid supply device 441 may supply the second fluid PF2 to the processing space PS. The second fluid supply device 441 may supply the second fluid PF2 in a supercritical state to the process chamber 410. When the second fluid PF2 in the supercritical state is supplied to the processing space PS, a residual liquid on the substrate W may be dissolved in the second fluid PF2 in the supercritical state. For example, the substrate drying apparatus 400 may dry the substrate W through the second fluid PF2 in the supercritical state.

The first fluid PF1 may be different from the second fluid PF2. For example, a critical point of the first fluid PF1 may be different from a critical point of the second fluid PF2. In some embodiments, a critical temperature of the first fluid PF1 may be less than a critical temperature of the second fluid PF2.

When a fluid is in a supercritical state, the physical properties of the fluid, such as a density, a viscosity, a diffusion coefficient, a polarity, etc., may change continuously from a gas-like state to a liquid-like state according to the change of pressure. When the fluid has a temperature greater than or equal to the critical temperature and a pressure greater than or equal to a critical pressure, the fluid becomes supercritical, may have gas-like diffusivity, viscosity, and surface tension, and may also have liquid-like solubility.

Since the second fluid PF2 in the supercritical state has a relatively small surface tension, the second fluid PF2 may penetrate into fine grooves between a plurality of fine patterns of the substrate W. When a drying process is performed on the substrate W by using the second fluid PF2 in the supercritical state, a residual liquid, such as a cleaning liquid, a rinsing liquid, etc., remaining on the surface of the substrate W may be removed while the leaning phenomenon occurring in the fine pattern on the substrate W may be suppressed.

The second fluid supply device 441 may be connected to the second supply pipe 442 penetrating the process chamber 410 through a second supply line SL2. The second fluid supply device 441 may spray the second fluid PF2 into the processing space PS through the second supply pipe 442. The second supply pipe 442 may be located in the upper wall 410UW of the process chamber 410. For example, the second supply pipe 442 may penetrate the upper wall 410UW of the process chamber 410.

In some embodiments, the second supply pipe 442 may extend upward from the upper face 413 of the process chamber 410. One end of the second supply pipe 442 may be located inside the process chamber 410, and the other end may be connected to the second fluid supply device 441 outside the process chamber 410.

In some embodiments, a cross-section of the second supply pipe 442 perpendicular to a direction of extension of the second supply pipe 442 may have a circular or oval shape. In some embodiments, the cross-section of the second supply pipe 442 perpendicular to the direction of extension of the second supply pipe 442 may also have a polygonal shape, such as a square.

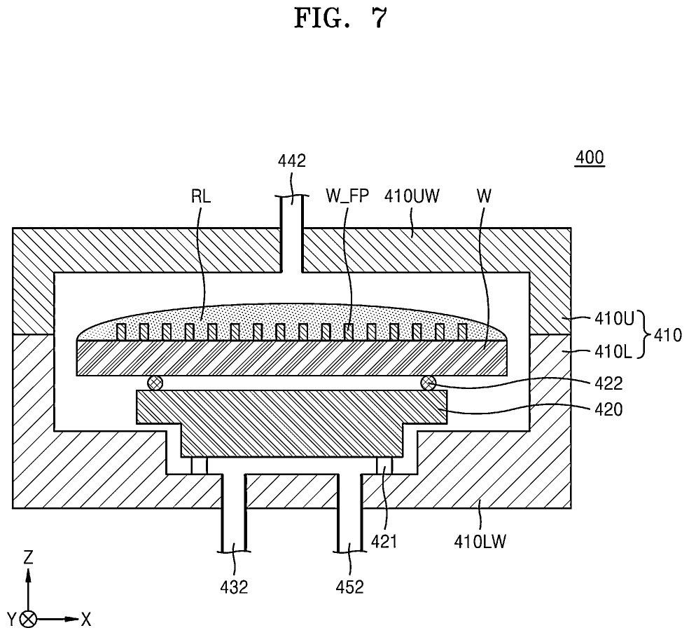

A residual liquid RL (see FIG. 7) located on the surface of the substrate W loaded onto the substrate drying apparatus 400 may include a rinsing liquid, a cleaning liquid, and an organic solution remaining after used during a liquid treating process by the substrate liquid treating apparatus 300 (see FIG. 1). For example, the residual liquid may include de-ionized water (DIW) or isopropyl alcohol (IPA).

Hereinafter, in this specification, “solubility” means the amount of a residual liquid dissolved (substituted) per the weight of a solvent (first fluid or second fluid). For example, the greater the solubility is, the greater a rate of dissolving (substituting) the residual liquid in the solvent is.

The solubility of the residual liquid in the first fluid PF1 may be a first solubility, and the solubility of the residual liquid in the second fluid PF2 may be a second solubility. The first solubility may be less than the second solubility. For example, the amount of the residual liquid dissolved per 100 g of the first fluid PF1 provided by the first fluid supply device 431 may be less than the amount of the residual liquid dissolved per 100 g of the second fluid PF2 provided by the second fluid supply device 441.

In some embodiments, when the surrounding environment affecting solubility other than the solvent is the same, the solubility of a residual liquid in the first fluid PF1 may be less than the solubility of the residual liquid in the second fluid PF2. For example, when the surrounding environment affecting the solubility is the same, the temperature of the first fluid PF1 may be the same as the temperature of the second fluid PF2, and the pressure of the first fluid PF1 may be the same as the pressure of the second fluid PF2. However, the surrounding environment affecting the solubility is not limited to the temperature and the pressure.

When the first fluid supply device 431 supplies the first fluid PF1 to the processing space PS, a relatively small amount of residual liquid is dissolved in the first fluid PF1, and when the second fluid supply device 441 supplies the second fluid PF2 to the processing space PS, a relatively large amount of the residual liquid may be dissolved in the second fluid PF2.

In some embodiments, the solubility of a residual liquid in a solvent may increase as the temperature of the solvent increases. For example, to suppress the dissolving of the residual liquid in the first fluid PF1 in the process of supplying the first fluid PF1 to the processing space PS, the first fluid supply device 431 may decrease the temperature of the first fluid PF1 until the first fluid PF1 having a pressure greater than the critical pressure becomes a liquid.

In some embodiments, the first fluid PF1 may include nitrogen (N₂), argon (Ar), or a combination thereof. In some embodiments, the second fluid PF2 may include hydrofluoroether (HFE), carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), sulfur hexafluoride (SF₆), acetone (C₃H₆O), or a combination thereof.

In some embodiments, when the first fluid PF1 and the second fluid PF2 are supplied to the processing space PS, the temperature of the first fluid PF1 may be less than or equal to the temperature of the second fluid PF2. For example, the temperature of the second fluid PF2 sprayed into the processing space PS may be about 50° C. to about 70° C., and the temperature of the first fluid PF1 sprayed into the processing space PS may be about 0° C. to about 50° C.

The substrate drying apparatus 400 may further include a controller 460. The controller 460 may control the first fluid supply device 431 and the second fluid supply device 441. For example, the controller 460 may control the time when the first fluid supply device 431 supplies the first fluid PF1 and the time when the second fluid supply device 441 supplies the second fluid PF2.

In some embodiments, the controller 460 may control the first fluid supply device 431 to supply the first fluid PF1 to the processing space PS in the operation of increasing the pressure of the processing space PS. The controller 460 may control the first fluid supply device 431 to supply the first fluid PF1 to the processing space PS until the pressure of the processing space PS reaches a process pressure that is greater than an initial pressure from the initial pressure. At this time, the controller 460 may control the second fluid supply device 441 to not supply the second fluid PF2 to the processing space PS. That is, the controller 460 may block the second fluid PF2 from being sprayed into the processing space PS until the pressure of the processing space PS reaches the process pressure.

In some embodiments, when the pressure of the processing space PS reaches a process pressure, the controller 460 may control the second fluid supply device 441 to supply the second fluid PF2 to the processing space PS. For example, when the pressure of the processing space PS reaches the process pressure, the controller 460 may spray the second fluid PF2 into the processing space PS and dissolve a residual liquid located on a surface of the substrate W in the second fluid PF2.

In the process of increasing the pressure of the processing space PS, when the upper portion of a plurality of fine patterns of the substrate W is exposed to the outside of the residual liquid, a phenomenon may occur in which the plurality of fine patterns collapse due to surface tension generated on the surface of the residual liquid located between the plurality of fine patterns. In the process of increasing the pressure of the processing space PS, since the first fluid PF1 fills the processing space PS, relatively little residual liquid may be dissolved. Accordingly, in the process of increasing the pressure of the processing space PS, a phenomenon in which some of the fine patterns of the substrate W are exposed to the outside of the residual liquid may be suppressed, and thus, the phenomenon in which the fine patterns collapse may be suppressed.

By varying the first fluid PF1 sprayed into the processing space PS when increasing the pressure of the processing space PS and the second fluid PF2 sprayed into the processing space PS when removing the residual liquid, the phenomenon in which the fine patterns of the substrate W collapse may be suppressed.

In some embodiments, the controller 460 may include a memory device such as read only memory (ROM), random access memory (RAM), etc., and a processor configured to perform certain operations and algorithms, for example, a microprocessor, a central processing unit (CPU), a graphics processing unit (GPU), etc.

The exhaust device 451 may be connected to an exhaust pipe 452 penetrating the process chamber 410 through an exhaust line EL. The exhaust device 451 may discharge a waste fluid DF within the processing space PS to the outside of the process chamber 410 through the exhaust pipe 452.

Here, the waste fluid DF may be defined as a fluid including various gases, chemicals, by-products, particles, etc. in the processing space PS. For example, the waste fluid DF may include the first fluid PF1 and second fluid PF2 in which the residual liquid is dissolved.

In some embodiments, the exhaust device 451 may include a vacuum pump, a collecting unit for collecting the waste fluid DF, and an opening/closing valve 451_V installed on the exhaust line EL. For example, to perform an exhaust operation through the exhaust device 451, the vacuum pump may reduce the pressure within the exhaust pipe 452 and suck the waste fluid DF within the processing space PS into the exhaust pipe 452. Also, the exhaust device 451 may control the pressure within the processing space PS by sucking and removing the waste fluid DF within the processing space PS.

In some embodiments, the exhaust pipe 452 may penetrate the lower wall 410LW of the process chamber 410. The exhaust pipe 452 may extend downward from the lower face 411 of the process chamber 410. One end of the exhaust pipe 452 may be located inside the process chamber 410, and the other end of the exhaust pipe 452 may be located outside the process chamber 410.

The exhaust pipe 452 may be connected to the exhaust device 451 through the exhaust line EL. Through an exhaust operation of the exhaust device 451, the waste fluid DF within the processing space PS may be sucked into the exhaust pipe 452. In some embodiments, the exhaust pipe 452 may have a circular or oval shape in a plan view. In some embodiments, the exhaust pipe 452 may also have a polygonal shape such as a square in a plan view.

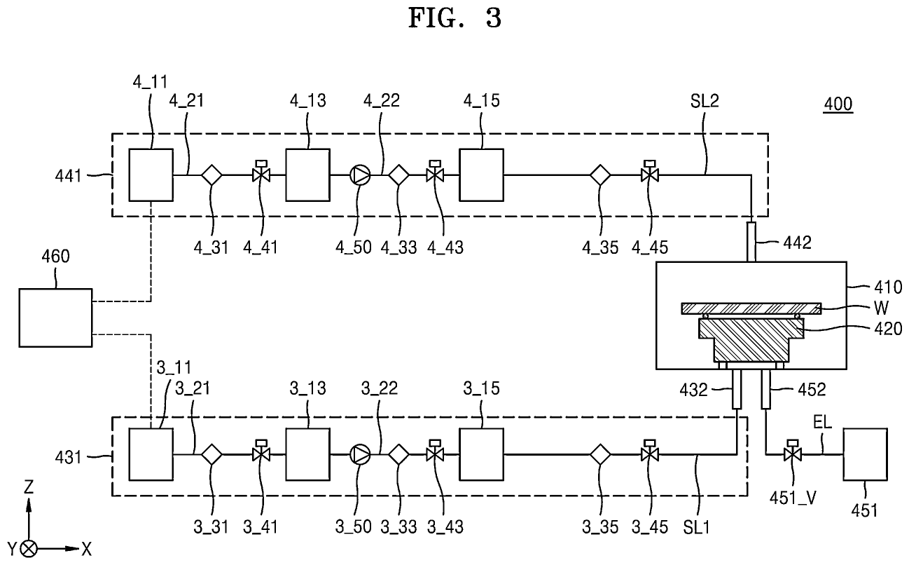

FIG. 3 is a schematic diagram illustrating the first fluid supply device 431 and the second fluid supply device 441 of the substrate drying apparatus 400 of FIG. 2.

The first fluid supply device 431 and the second fluid supply device 441 of the substrate drying apparatus 400 are described in detail with reference to FIGS. 2 and 3.

The first fluid supply device 431 may include a first fluid supply tank 3_11, a first condenser 3_13, a first pump 3_50, and a first storage tank 3_15.

The first fluid supply tank 3_11 may include raw materials. For example, the first fluid supply tank 3_11 may store a first fluid PF1 in a gaseous state. The first condenser 3_13 may change a phase of the first fluid PF. The first condenser 3_13 may cool the first fluid PF1 so that the first fluid PF1 changes from the gaseous state to a liquid state. In some embodiments, when the first fluid PF1 is stored in a high-pressure liquid state in the first fluid supply tank 3_11, the first condenser 3_13 may be omitted.

In some embodiments, a filter 3_31 for filtering out impurities within the first fluid PF1 and a valve 3_41 for controlling the flow of the first fluid PF1 may be installed on a first pipe 3_21 connecting the first fluid supply tank 3_11 with the first condenser 3_13.

In some embodiments, the first pump 3_50 may be installed on a second pipe 3_22 extending between the first condenser 3_13 and the first storage tank 3_15. The first pump 3_50 may drive the first fluid PF1 so that the first fluid PF1 liquefied by the first condenser 3_13 moves to the first storage tank 3_15 along the second pipe 3_22. A filter 3_33 for filtering out impurities within the first fluid PF1 and a valve 3_43 for controlling the flow of the processing fluid PF may be installed on the second pipe 3_22 connecting the first condenser 3_13 with the first storage tank 3_15.

The first storage tank 3_15 may store the first fluid PF1 and may phase change the first fluid PF1 to a supercritical state. The first storage tank 3_15 may store the first fluid PF1 at a pressure greater than or equal to a critical pressure of the first fluid PF1. The first storage tank 3_15 may heat the first fluid PF1 to a temperature greater than or equal to a critical temperature of the first fluid PF1 through a built-in heater.

For example, the pressure of the first fluid PF1 stored in the first storage tank 3_15 may be about 170 bar to about 200 bar. The temperature of the first fluid PF1 stored in the first storage tank 3_15 may be about 0° C. to about 50° C.

The first fluid PF1 discharged from the first storage tank 3_15 may move to the first supply pipe 432 along the first supply line SL1. In some embodiments, a valve 3_45 for controlling the flow of the first fluid PF1 and a filter 3_35 for filtering out impurities within the first fluid PF1 may be installed on the first supply line SL1.

When the first storage tank 3_15 stores the first fluid PF1 at a pressure greater than a process pressure, when the valve 3_45 installed on the first supply line SL1 is opened, the first fluid PF1 may move to the processing space PS due to the pressure difference between the first storage tank 3_15 and the processing space PS. However, a pump for moving the fluid PF1 from the first storage tank 3_15 to the processing space PS when the first storage tank 3_15 stores the first fluid PF1 at a pressure less than the process pressure may be additionally installed in the first supply line SL1.

The second fluid supply device 441 may include a second fluid supply tank 4_11, a second condenser 4_13, a first pump 4_50, and a second storage tank 4_15.

The second fluid supply tank 4_11 may include raw materials. For example, the second fluid supply tank 4_11 may store a second fluid PF2 in a gaseous state. The second condenser 4_13 may change the phase of the second fluid PF2. The second condenser 4_13 may cool the second fluid PF2 so that the second fluid PF2 changes from the gaseous state to a liquid state. In some embodiments, when the second fluid PF2 is stored in a high-pressure liquid state in the second fluid supply tank 4_11, the second condenser 4_13 may be omitted.

In some embodiments, a filter 4_31 for filtering out impurities within the second fluid PF2 and a valve 4_41 for controlling the flow of the second fluid PF2 may be installed on a first pipe 4_21 connecting the second fluid supply tank 4_11 with the second condenser 4_13.

In some embodiments, the second pump 4_50 may be installed on a second pipe 4_22 extending between the second condenser 4_13 and the second storage tank 4_15. The second pump 4_50 may drive the second fluid PF2 so that the second fluid PF2 liquefied by the second condenser 4_13 moves to the second storage tank 4_15 along the second pipe 4_22.

A filter 4_33 for filtering out impurities within the second fluid PF2 and a valve 4_43 for controlling the flow of the processing fluid PF may be installed on the second pipe 4_22 connecting the second condenser 4_13 with the second storage tank 4_15.

The second storage tank 4_15 may store the second fluid PF2 and phase change the second fluid PF2 to a supercritical state. The second storage tank 4_15 may store the second fluid PF2 at a pressure greater than or equal to a critical pressure of the second fluid PF2. The second storage tank 4_15 may heat the second fluid PF2 to a temperature greater than or equal to a critical temperature of the second fluid PF2 through a built-in heater.

For example, the pressure of the second fluid PF2 stored in the second storage tank 4_15 may be about 170 bar to about 200 bar. The temperature of the second fluid PF2 stored in the second storage tank 4_15 may be about 50° C. to about 70° C.

In some embodiments, the pressure of the first fluid PF1 stored in the first storage tank 3_15 may be substantially the same as the pressure of the second fluid PF2 stored in the second storage tank 4_15. The temperature of the first fluid PF1 stored in the first storage tank 3_15 may be less than or equal to the temperature of the second fluid PF2 stored in the second storage tank 4_15.

The second fluid PF2 discharged from the second storage tank 4_15 may move to the second supply pipe 442 along the second supply line SL2. In some embodiments, a valve 4_45 for controlling the flow of the second fluid PF2 and a filter 4_35 for filtering out impurities within the second fluid PF2 may be installed on the second supply line SL2.

When the second storage tank 4_15 stores the second fluid PF2 at a pressure greater than the process pressure, when the valve 4_45 installed on the second supply line SL2 is opened, the second fluid PF2 may move to the processing space PS due to the pressure difference between the second storage tank 4_15 and the processing space PS. However, a pump for moving the second fluid PF2 from the second storage tank 4_15 to the processing space PS when the second storage tank 4_15 stores the second fluid PF2 at a pressure less than the process pressure may be additionally installed on the second supply line SL2.

In some embodiments, the controller 460 may control at least one of the valves 3_41, 3_43, and 3_45 of the first fluid supply device 431 to adjust the supply of the first fluid PF1 and may control at least one of the valves 4_41, 4_43, and 4_45 of the second fluid supply device 441 to adjust the supply of the second fluid PF2.

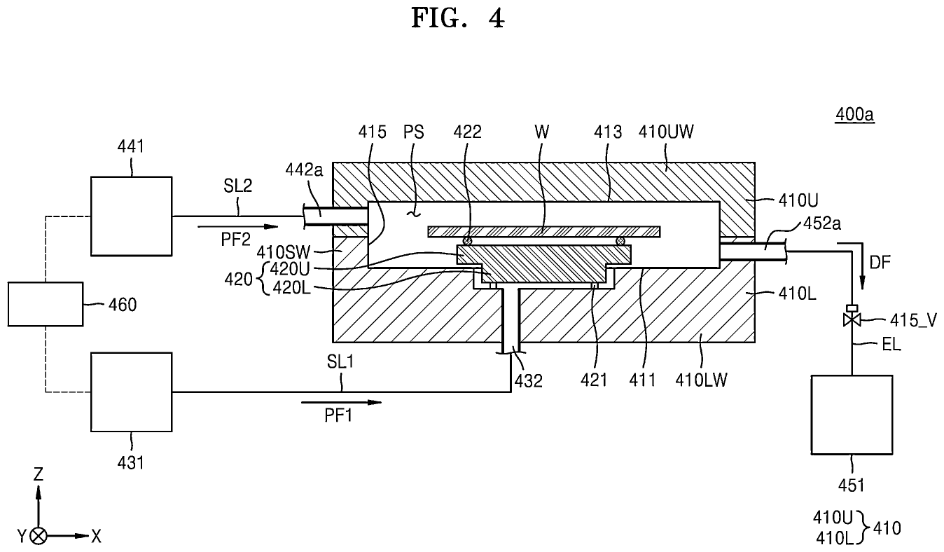

FIG. 4 is a cross-sectional view schematically illustrating a substrate drying apparatus 400a according to an embodiment.

Most of components constituting the substrate drying apparatus 400a described below and materials of the components are substantially the same or similar to those previously described with reference to FIG. 2. Therefore, for convenience of explanation, a description will made focusing on a difference between the substrate drying apparatus 400a of FIG. 4 and the substrate drying apparatus 400 of FIG. 2.

Referring to FIG. 4, the substrate drying apparatus 400a may include a second supply pipe 442a and an exhaust pipe 452a.

The second supply pipe 442a may include a pipe which is connected to the second fluid supply device 441 and through which the second fluid PF2 is sprayed into the processing space PS. The exhaust pipe 452a may include a pipe which is connected to the exhaust device 451 and through which the waste fluid DF is discharged.

For example, the residual liquid located on the surface of the substrate W is dissolved in the second fluid PF2 that is sprayed into the processing space PS through the second supply pipe 442a, and the second fluid PF2 dissolving the residual liquid that is part of the waste fluid DF may be discharged to the outside of the process chamber 410 through the exhaust pipe 452a.

The second supply pipe 442a and the exhaust pipe 452a may be spaced apart with the substrate W located therebetween. For example, the second supply pipe 442a and the exhaust pipe 452a may be arranged so that the second fluid PF2 sprayed from the second supply pipe 442a passes the upper portion of the substrate W and moves to the exhaust pipe 452a.

In some embodiments, the second supply pipe 442a and the exhaust pipe 452a may penetrate the side wall 410SW of the process chamber 410. The second supply pipe 442a may extend from the side face 415 of the process chamber 410 to the outside of the process chamber 410, and the exhaust pipe 452a may extend from the side face 415 of the process chamber 410 to the outside of the process chamber 410.

In some embodiments, the second supply pipe 442a and the exhaust pipe 452a may be spaced apart in the diameter direction of the substrate W. For example, the second supply pipe 442a and the exhaust pipe 452a may be point symmetrical with respect to the center of the substrate W.

In some embodiments, the second supply pipe 442a and the exhaust pipe 452a may have different vertical levels. For example, the second supply pipe 442a may be located above the substrate support 420, and the exhaust pipe 452a may be located below the substrate support 420.

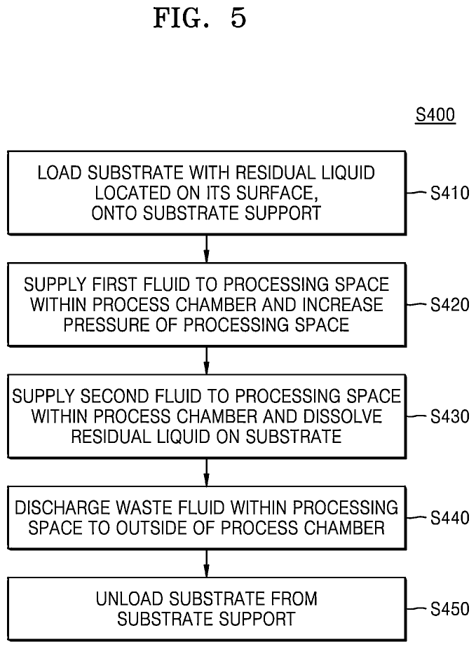

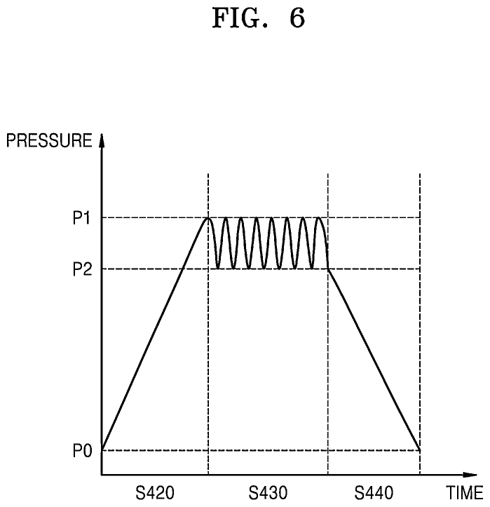

FIG. 5 is a flowchart illustrating a substrate drying method S400 according to an embodiment. FIG. 6 is a graph illustrating the change of pressure of a processing space PS while substrate drying is in progress. FIGS. 7 to 10 are cross-sectional views illustrating the substrate drying method S400 in accordance with a process sequence according to an embodiment.

Referring to FIG. 5 together with the other figures, the substrate drying method S400 may include the operations of loading the substrate W with a residual liquid RL located on its surface, onto the substrate support 420 (S410), increasing the pressure of the processing space PS by supplying the first fluid PF1 to the processing space PS of the process chamber 410 (S420), dissolving the residual liquid RL located on the substrate W in the second fluid PF2 by supplying the second fluid PF2 in a supercritical state to the processing space PS of the process chamber 410 (S430), discharging the waste fluid DF within the processing space PS to the outside of the process chamber 410 (S440), and unloading the substrate W from the substrate support 420 (S450).

The substrate drying method S400 of the substrate drying apparatus 400 is described below with reference to FIGS. 6 to 10 together with FIG. 2.

Referring to FIG. 7, the substrate W with the residual liquid RL located on its surface may be loaded onto the substrate support 420. The substrate W may include a plurality of fine patterns W_FP protruding upward from an upper face of the substrate W. The residual liquid RL may be located between the plurality of fine patterns W_FP, and the plurality of fine patterns W_FP may be completely covered with the residual liquid RL.

While the substrate W is loaded into the processing space PS, the process chamber 410 may be in an open state. The substrate W may be seated on the substrate support 420. When the substrate W is seated on the substrate support 420, the process chamber 410 may be converted from an open state to a closed state so that the processing space PS is sealed from the outside of the process chamber 410.

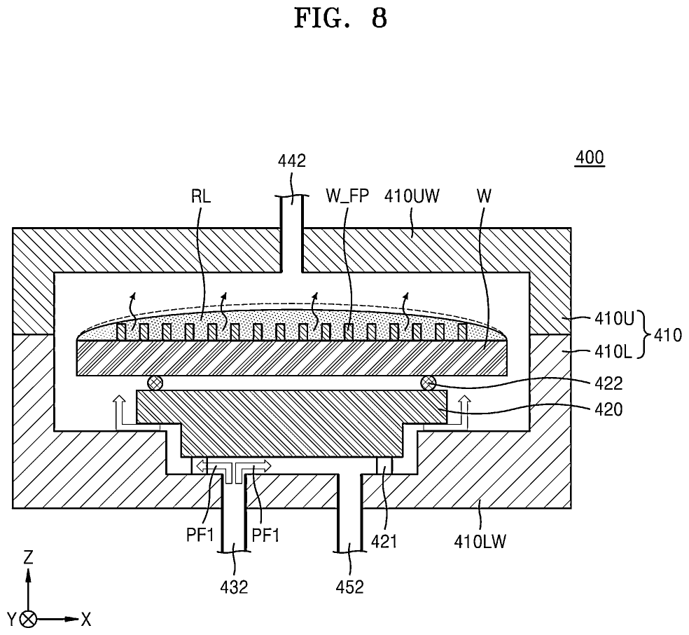

Referring to FIG. 8, after the substrate W loading operation, the first fluid PF1 may be supplied to the processing space PS so that the processing space PS is filled with the first fluid PF1. The first fluid supply device 431 may supply the first fluid PF1 in a gaseous state or supercritical state to the processing space PS and increase the pressure of the processing space PS from an initial pressure P0 similar to the atmospheric pressure to a process pressure P1 (see FIG. 6). In some embodiments, the process pressure P1 may be greater than a critical pressure of the first fluid PF1 and may be about 120 bar to about 170 bar.

In the operation of increasing the pressure of the processing space PS, a small amount of residual liquid RL may be dissolved in the first fluid PF1. However, since the solubility of the residual liquid RL in the first fluid PF1 is relatively low, the plurality of fine patterns W_FP of the substrate W may still be completely covered with the residual liquid RL. For example, the surface of the residual liquid RL may not be located between the plurality of fine patterns W_FP.

In the operation of increasing the pressure of the processing space PS up to reaching the process pressure P1, a phenomenon may be suppressed in which fine patterns located at an edge of the substrate W among the plurality of fine patterns W_FP are exposed to the outside of the residual liquid RL, by filling the processing space PS with the first fluid PF1 failing to dissolve the residual liquid RL quickly. Accordingly, a phenomenon may be suppressed in which the plurality of fine patterns W_FP collapse due to a surface tension of the residual liquid RL.

In the operation of increasing the pressure of the processing space PS, the second fluid supply device 441 may not supply the second fluid PF2 to the processing space PS. For example, in the operation of increasing the pressure of the processing space PS, when the second fluid PF2 having a relatively high solubility of the residual liquid RL is supplied, a phenomenon of exposing the plurality of fine patterns W_FP to the outside of the residual liquid RL may occur and thus, a phenomenon of damaging the substrate W may occur.

In some embodiments, the first fluid PF1 may be sprayed into the processing space PS through the first supply pipe 432 penetrating the lower wall 410LW of the process chamber 410. The first supply pipe 432 overlaps the substrate support 420 in a vertical direction (Z direction) and may be located below the substrate support 420. Accordingly, the first fluid PF1 sprayed from the first supply pipe 432 may fill the processing space PS without being sprayed directly onto the substrate W.

In some embodiments, the operation of increasing the pressure of the processing space PS (S420) may include a first supply operation of supplying the first fluid PF1 of a first temperature to the processing space PS, and a second supply operation of supplying the first fluid PF1 of a second temperature to the processing space PS. In some embodiments, in the first supply operation, the first temperature of the first fluid PF1 may be between about 0° C. and about 30° C. In the second supply operation, the second temperature of the first fluid PF1 may be between about 30° C. and about 50° C.

In some embodiments, the first supply operation may be performed until the pressure of the processing space PS reaches a target middle pressure between the initial pressure P0 and the process pressure P1, and for example, the target middle pressure may be between about 60 bar and about 90 bar. When the pressure of the processing space PS reaches the target middle pressure through the first supply operation, the second supply operation may be performed. The second supply operation may be performed until the pressure of the processing space PS reaches the process pressure P1.

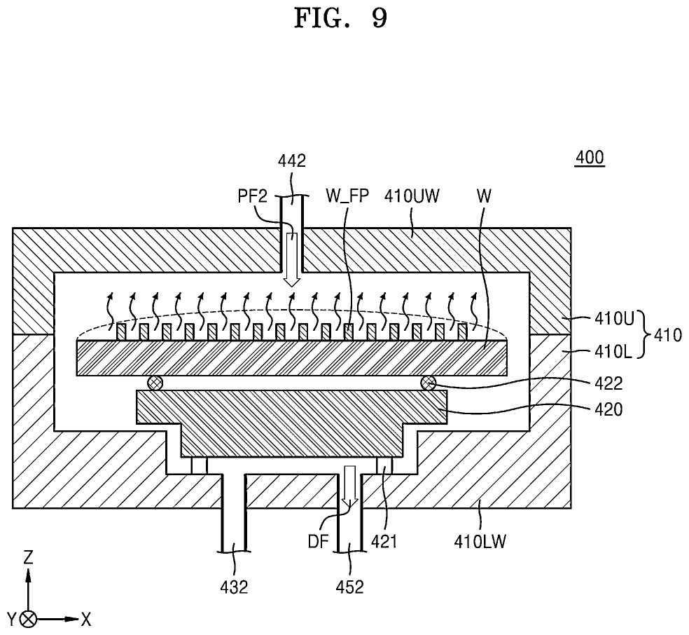

Referring to FIG. 9, the second fluid PF2 may be supplied to the processing space PS, the residual liquid RL may be dissolved in the second fluid FP2, and the residual liquid RL may be removed from the substrate W.

When the pressure of the processing space PS reaches the process pressure P1, the second fluid PF2 may be supplied to the processing space PS. The residual liquid RL located on the substrate W may be dissolved in (or substituted with) the second fluid PF2.

In the operation of dissolving the residual liquid RL, the first fluid supply device 431 may not supply the first fluid PF1 to the processing space PS. For example, compared to the second fluid PF2, the first fluid PF1 may have a lower solubility of the residual liquid RL in the same surrounding environment, and thus the efficiency of removing the residual liquid RL may be relatively low. That is, in the operation of dissolving the residual liquid RL, the substrate drying apparatus 400 may supply only the second fluid PF2 to the processing space PS, thereby efficiently proceeding with the dissolution of the residual liquid RL.

In some embodiments, the second fluid supply device 441 may supply the second fluid PF2 of a third temperature to the processing space PS. In the operation of dissolving the residual liquid RL, the third temperature of the second fluid PF2 may be greater than or equal to the second temperature of the first fluid PF1 in the second supply operation. For example, in the operation of dissolving the residual liquid RL, the third temperature of the second fluid PF2 may be greater than a critical temperature of the second fluid PF2. In some embodiments, in the operation of dissolving the residual liquid RL, the third temperature of the second fluid PF2 may be between about 50° C. and about 70° C.

In some embodiments, the second fluid PF2 may be sprayed into the processing space PS through the second supply pipe 442 penetrating the upper wall 410UW of the process chamber 410. For example, the second supply pipe 442 may be located above the substrate support 420. Accordingly, the second fluid PF2 may improve the quality of the substrate W, by suppressing a phenomenon in which impurities generated when the residual liquid RL is dissolved are floated on the upper portion of the substrate W.

In some embodiments, in the process of dissolving the residual liquid RL in the second fluid PF2, a pressure decrease process of discharging the second fluid PF2 in which the residual liquid RL is dissolved to the outside of the process chamber 410 and decreasing the pressure of the processing space PS from the process pressure P1 to an exhaust pressure P2 less than the process pressure P1, and a pressure increase process of supplying the second fluid PF2 to the process chamber 410 and increasing the pressure of the processing space PS from the exhaust pressure P2 to the process pressure P1 may be repeated (see FIG. 6). In some embodiments, the pressure decrease process and the pressure increase process may be alternately repeated two or more times until the residual liquid RL is removed from the substrate W.

In some embodiments, in the process of dissolving the residual liquid RL in the second fluid PF2, the second fluid supply device 441 may continuously supply the second fluid PF2 to the processing space PS, and the exhaust device 451 may continuously discharge the waste fluid DF from the processing space PS. The speed at which the second fluid supply device 441 supplies the second fluid PF2 may be the same as the speed at which the exhaust device 451 discharges the waste fluid DF. Accordingly, while the pressure of the processing space PS is maintained constant, the residual liquid RL may be removed from the substrate W.

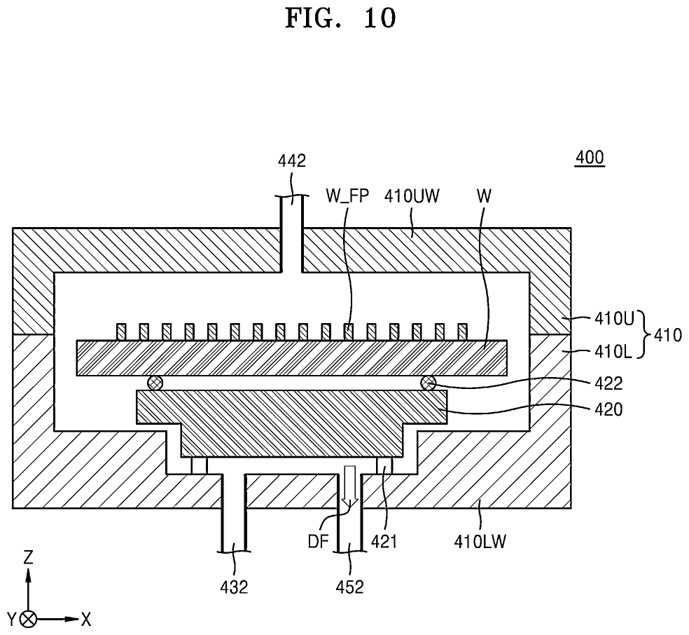

Referring to FIG. 10, after the residual liquid RL is completely removed from the substrate W, the exhaust device 451 may exhaust the waste fluid DF in the processing space PS and decrease the pressure of the processing space PS to the initial pressure P0. When the pressure of the processing space PS reaches the initial pressure P0, the process chamber 410 may be converted from the closed state to the open state, and the substrate W may be unloaded from the substrate support 420.

So far, the present disclosure has been described with reference to the embodiments shown in the drawings, but these are merely illustrative, and those skilled in the art will understand that various modifications and other equivalent embodiments are possible therefrom. Therefore, the true scope of technical protection of the present disclosure should be defined by the technical spirit of the attached claims.

While the present disclosure has been particularly shown and described with reference to embodiments thereof, it will be understood that various changes in form and details may be made therein without departing from the spirit and scope of the following claims.

What is claimed is:

1. A substrate drying apparatus comprising:
a process chamber comprising a processing space for drying a residual liquid located on a surface of a substrate;
a substrate support configured to support the substrate within the process chamber;
a first fluid supply device configured to supply a first fluid to the processing space through a first supply pipe penetrating the process chamber, wherein the solubility of the residual liquid in the first fluid is a first solubility;
a second fluid supply device configured to supply a second fluid in a supercritical state to the processing space through a second supply pipe penetrating the process chamber, wherein the solubility of the residual liquid in the second fluid is a second solubility that is greater than the first solubility; and
an exhaust device configured to discharge a waste fluid within the processing space of the process chamber to outside the process chamber through an exhaust pipe penetrating the process chamber.

2. The substrate drying apparatus of claim 1, wherein a critical temperature of the first fluid is less than a critical temperature of the second fluid.

3. The substrate drying apparatus of claim 1, wherein a temperature of the first fluid when the first fluid supply device supplies the first fluid to the processing space is less than or equal to a temperature of the second fluid when the second fluid supply device supplies the second fluid to the processing space.

4. The substrate drying apparatus of claim 1, wherein the first supply pipe penetrates a lower wall of the process chamber and is located below the substrate support.

5. The substrate drying apparatus of claim 4, wherein the second supply pipe is located above the substrate support and penetrates an upper wall of the process chamber, and
wherein the exhaust pipe penetrates a lower wall of the process chamber.

6. The substrate drying apparatus of claim 1, further comprising a controller configured to control the first fluid supply device and the second fluid supply device,
wherein the controller is configured to:
control the first fluid supply device to supply the first fluid to the processing space of the process chamber until a pressure of the processing space of the process chamber changes from an initial pressure to a process pressure that is greater than the initial pressure; and
control the second fluid supply device to supply the second fluid to the processing space of the process chamber when the pressure of the processing space of the process chamber reaches the process pressure.

7. A substrate drying method comprising:
loading a substrate with a residual liquid located on its surface onto a substrate support within a process chamber;
supplying a first fluid to a processing space within the process chamber and increasing a pressure of the processing space;
supplying a second fluid in a supercritical state to the processing space within the process chamber and dissolving the residual liquid located on the surface of the substrate; and
discharging a waste fluid within the processing space to outside the process chamber,
wherein the solubility of the residual liquid in the first fluid is less than the solubility of the residual liquid in the second fluid.

8. The method of claim 7, wherein a temperature of the first fluid supplied to the processing space in an operation of increasing the pressure of the processing space is less than or equal to a temperature of the second fluid supplied to the processing space in an operation of dissolving the residual liquid.

9. The method of claim 7, wherein the substrate comprises a plurality of fine patterns protruding upward from an upper face of the substrate, and
wherein in an operation of loading the substrate to the processing space, the residual liquid covers the plurality of fine patterns of the substrate.

10. The method of claim 9, wherein in an operation of increasing the pressure of the processing space, the residual liquid covers the plurality of fine patterns of the substrate even if part of the residual liquid is dissolved in the first fluid.

11. The method of claim 10, wherein in an operation of increasing the pressure of the processing space, the second fluid is not supplied to the processing space and only the first fluid is supplied to the processing space.

12. The method of claim 7, wherein in an operation of dissolving the residual liquid, the first fluid is not supplied to the processing space and only the second fluid is supplied to the processing space.

13. The method of claim 7, wherein the first fluid is supplied to the processing space through a first supply pipe that is located below the substrate support and penetrates a lower wall of the process chamber.

14. The method of claim 13, wherein the second fluid is supplied to the processing space through a second supply pipe that is located above the substrate support and penetrates a side wall of the process chamber, and
wherein the waste fluid is exhausted to outside the process chamber through an exhaust pipe that penetrates a side wall of the process chamber and is located below the substrate.

15. The method of claim 13, wherein the second fluid is supplied to the processing space through a second supply pipe that is located above the substrate support and penetrates an upper wall of the process chamber, and
wherein the waste fluid is exhausted to outside the process chamber through an exhaust pipe that penetrates a lower wall of the process chamber.

16. The method of claim 7, wherein a critical point of the first fluid is different from a critical point of the second fluid.

17. The method of claim 16, wherein a critical temperature of the first fluid is less than a critical temperature of the second fluid.

18. The method of claim 16, wherein the residual liquid comprises isopropyl alcohol (C₃H₈O),
wherein the first fluid comprises at least one of nitrogen (N₂) and argon (Ar), and
wherein the second fluid comprises at least one of hydrofluoroether (HFE) and carbon dioxide (CO₂).

19. A substrate drying method comprising:
loading a substrate with a residual liquid located on its surface onto a substrate support within a process chamber;
supplying, by a first fluid supply device, a first fluid in a supercritical state to a processing space within the process chamber and increasing a pressure of the processing space;
supplying, by a second fluid supply device, a second fluid in a supercritical state to the processing space within the process chamber and dissolving the residual liquid located on the surface of the substrate in the second fluid; and
discharging a waste fluid within the processing space to outside the process chamber,
wherein the substrate comprises a plurality of fine patterns protruding upward from an upper face of the substrate,
wherein in an operation of increasing the pressure of the processing space, the residual liquid covers the plurality of fine patterns of the substrate,
wherein the second fluid is supplied to the processing space when the pressure of the processing space reaches a process pressure,
wherein the first fluid and the second fluid have different constituent materials, and
wherein the solubility of the residual liquid in the first fluid is less than the solubility of the residual liquid in the second fluid.

20. The method of claim 19, wherein the residual liquid comprises isopropyl alcohol (C₃H₈O),
wherein the first fluid comprises at least one of nitrogen (N₂) and argon (Ar), and
wherein the second fluid comprises at least one of hydrofluoroether (HFE) and carbon dioxide (CO₂).
